(19) United States
(12) Patent Application Publication
(10) Pub. No.: US 2008/0035947 A1
(43) Pub. Date: Feb. 14, 2008

(54) Surface Mount Light Emitting Chip Package

(76) Inventors: Stanton Earl Weaver Jr., Northville, NY (US); Chen-Lun Hsing Chen, North Olmsted, OH (US); Boris Kolodin, Beachwood, OH (US); Thomas Elliot Stecher, Scotia, NY (US); James Reginelli, Parma, OH (US); Deborah Ann Haitko, Schenectady, NY (US); Xiang Gao, Edison, NJ (US); Ivan Eliashevich, Maplewood, NJ (US)

Correspondence Address: FAY SHARPE LLP, 1100 SUPERIOR AVENUE, SEVENTH FLOOR, CLEVELAND, OH, 44114, US

(21) Appl. No.: 10/582,377

(22) PCT Filed: Dec. 9, 2004
(86) PCT No.: PCT/US04/41392

§ 371 Date: Mar. 29, 2007

Related U.S. Application Data
(60) Provisional application No. 60/527,969, filed on Dec. 9, 2003.

(51) Int. Cl. H01L 33/00

(52) U.S. Cl. 257/99; 257/E33.057

(57) ABSTRACT

A surface mount light emitting package includes a chip carrier having top and bottom principal surfaces. At least one light emitting chip is attached to the top principal surface of the chip carrier. A lead frame attached to the top principal surface of the chip carrier. When surface mounted to an associated support, the bottom principal surface of the chip carrier is in thermal contact with the associated support without the lead frame intervening therebetween.

This application claims the benefit of U.S. provisional application Ser. No. 60/527,969 filed on Dec. 9, 2003.

### BACKGROUND

The following relates to the lighting arts. It is especially relates to surface-mounted light emitting diodes for indicator lights, illumination applications, and the like, and will be described with particular reference thereto. However, the following will also find application in other areas that advantageously can employ surface-mountable light emitting devices.

Surface mounted light emitting packages typically employ a light emitting chip such as a light emitting diode chip, a vertical cavity surface emitting laser, or the like. In some arrangements the chip is bonded to a thermally conductive sub-mount which is in turn bonded to a lead frame. The sub-mount provides various benefits such as improving manufacturability of electrical interconnections, improving thermal contact and conduction, and the like. The lead frame is adapted to be surface mounted by soldering to a printed circuit board or other support.

Such arrangements have certain disadvantages. The thermal transfer path includes two intervening elements, namely the sub-mount and the lead frame. Moreover, electrical connections to the lead frame typically involve wire bonds, which can be fragile. The mechanical connection between the sub-mount and the lead frame is typically effected in part by an epoxy or other type of encapsulating overmolding material. Such materials can have relatively high coefficients of thermal expansion which can stress wire bonds or mechanical connections.

The present invention contemplates an improved apparatus and method that overcomes the above-mentioned limitations and others.

### BRIEF SUMMARY

According to one aspect, a light emitting package is disclosed. A chip carrier includes top and bottom principal surfaces. At least one light emitting chip is attached to the top principal surface of the chip carrier. A lead frame attached to the top principal surface of the chip carrier.

According to another aspect, a light emitter is disclosed. A chip carrier has top and bottom principal surfaces. At least one light emitting chip is attached to the top principal surface of the chip carrier. A lead frame electrically contacts electrodes of the at least one light emitting chip. A support including printed circuitry is provided. The lead frame electrically contacts the printed circuitry. The chip carrier is secured to the support without the lead frame intervening therebetween.

According to yet another aspect, a light emitting package comprises a chip carrier and a light emitting chip attached to the chip carrier.

According to still yet another aspect, a light emitting package comprises a light emitting chip and a lead frame electrically connected to electrodes of the light emitting chip.

Numerous advantages and benefits of the present invention will become apparent to those of ordinary skill in the art upon reading and understanding the present specification.

### BRIEF DESCRIPTION OF THE DRAWINGS

The invention may take form in various components and arrangements of components, and in various process operations and arrangements of process operations. The drawings are only for purposes of illustrating preferred embodiments and are not to be construed as limiting the invention. The drawings of the light emitting packages are not to scale.

FIG. 1 shows a side view of a light emitting package surface mounted to a printed circuit board.

FIGS. 2A and 2B show top and side views of another light emitting package.

FIG. 3 shows a top view of yet another light emitting package.

FIGS. 4A, 4B, and 4C show, respectively, a top view of a chip carrier with four light emitting chips flip-chip bonded thereto, a top view of a lead frame, and a side view of a light emitting package constructed from the components of FIGS. 4A and 4B.

FIGS. 5A, 5B, and 5C show, respectively, a top view of a chip carrier with four light emitting chips bonded thereto with a front-side electrode of each chip wire bonded to the chip carrier, a top view of a lead frame, and a side view of a light emitting package constructed from the components of FIGS. 5A and 5B.

### DETAILED DESCRIPTION OF PREFERRED EMBODIMENTS

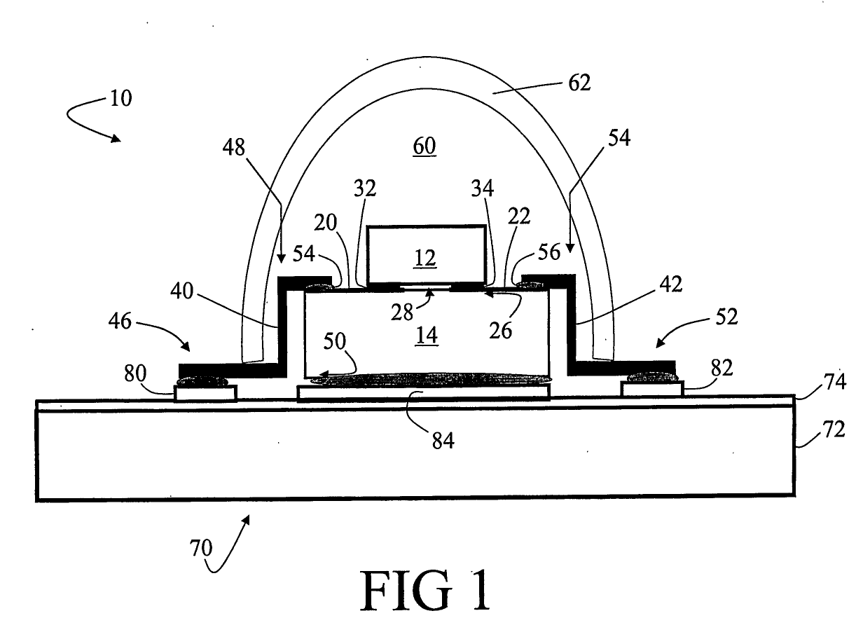

With reference to FIG. 1, a surface-mounted light emitting package 10 includes a light emitting chip 12, such as a light emitting diode, a resonant cavity light emitting diode, a vertical cavity surface emitting laser, or the like, bonded to an electrically insulating chip carrier 14. In FIG. 1, a flip-chip bonding configuration is shown in which front-side electrodes of the light emitting chip 12 are bonded to electrically conductive layers 20, 22 disposed on a top principal surface 26 of the chip carrier 14. An insulating gap 28 which may be an air gap or may be filled with an electrically insulating material such as an epoxy or other dielectric. The electrically conductive layers 20, 22 define first and second terminals of opposite electrical polarity. Flip-chip electrode bonds 32, 34 can be thermosonic bonds, conductive epoxy bonds, solder bonds, or the like.

The chip carrier 14 is preferably substantially thermally conductive. At least the top principal surface 26 of the chip carrier 14 is substantially electrically insulating. The chip carrier 14 can be made of an electrically insulating material such as semi-insulating silicon, a ceramic, or a thermally conductive but electrically insulating plastic. Alternatively, the chip carrier 14 can be made of an electrically conductive material with an insulating layer or coating applied at least to the top principal surface 26. For example, the chip carrier 14 can be made of conductive silicon with a silicon dioxide layer disposed on the top principal surface 26, or the chip carrier 14 can be made of a metal with an insulator disposed on the top principal surface 26, or so forth.

The electrically conductive layers 20, 22 extend away from the die attach region where the light emitting chip 12 is flip chip bonded. Lead frame elements 40, 42, which are electrically conductive and electrically isolated from one another, are secured to and electrically contact portions of the electrically conductive layers 20, 22 distal from the die attach region. The lead frame 40, 42 is attached to the top principal surface 26 of the chip carrier 14. The lead frame element 40 includes an electrical lead 46 distal from the chip carrier 14 and a bend 48 such that the lead 46 is approximately coplanar with a bottom principal surface 50 of the chip carrier 14. Similarly, the lead frame element 42 includes an electrical lead 52 distal from the chip carrier 14 and a bend 54 such that the lead 52 is approximately coplanar with the bottom principal surface 50 of the chip carrier 14. Electrical and physical bonding of the lead frame elements 40, 42 to the top principal surface 26 of the chip carrier 14 is suitably achieved by solder bonds 54, 56. The lead frame 40, 42 is suitably made of copper or another highly conductive material.

An overmolding or encapsulant 60 is disposed over the light emitting chip 12 and the top principal surface 26 of the chip carrier 14, and also encapsulates a portion of the lead frame elements 40, 42 proximate to the chip carrier 14. The leads 46, 52 of the lead frame 40, 42 as well as the bottom principal surface 50 of the chip carrier 14 extend outside of the encapsulant 60. Optionally, a wavelength-converting phosphor layer 62 coats the encapsulant 60 and fluorescently or phosphorescently converts light emitted by the light emitting chip 12 to another wavelength or range or plurality of wavelengths.

The chip carrier 14 and the light emitting chip 12 and lead frame 40, 42 bonded to the top principal surface 26 of the chip carrier 14, together with the optional encapsulant 60 and phosphor layer 62, collectively define a surface mountable unit that is surface-mounted on a printed circuit board 70. In the example embodiment of FIG. 1, the printed circuit board 70 includes a metal board 72, such as a copper or aluminum board, with an insulating coating 74 disposed on the metal board 72. Printed traces are disposed on the insulating coating 74 and define a selected electrical circuit or circuits including electrical terminals, bonding bumps, or bonding pads 80, 82. The lead 46 of the lead frame element 40 is soldered to the printed circuitry electrical terminal 80, while the lead 52 of the lead frame element 42 is soldered to the printed circuitry electrical terminal 82. The printed traces also includes a thermal terminal 84 which optionally is not connected with the electrical circuitry. The bottom principal surface 50 of the chip carrier 14 is preferably soldered or otherwise bonded to the thermal terminal 84 to provide a substantially thermally conductive pathway therebetween, so that heat generated in the light emitting chip 12 can conduct through the substantially thermally conductive chip carrier 14 to the thermal terminal 84 and thence to the printed circuit board 70. Optionally, the bottom principal surface 50 of the chip carrier 14 includes a metal layer for solder attach to the board or other coating to enhance thermal contact and heat transfer.

In one embodiment, the attachment bonding the leads 46, 52 to the terminals 80, 82 and the attachment bonding the bottom principal surface 50 of the chip carrier 14 to the thermal terminal 84 are the same. For example, these attachments can all be made by solder bonds in a single bonding process. Alternatively, a different type of attachment is used for bonding the bottom principal surface 50 of the chip carrier 14 to the thermal terminal 84 as compared with the type of attachment used for bonding the leads 46, 52 to the terminals 80, 82. In this latter approach, the thermal attachment of the chip carrier 14 and the electrical attachments of the leads 46, 52 can be separately optimized for thermal and electrical conductance, respectively.

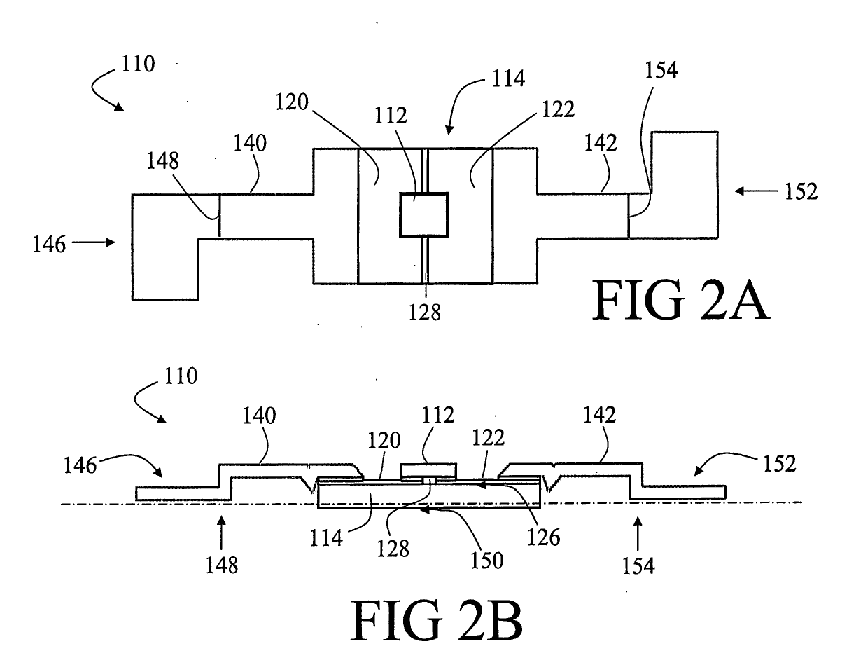

FIGS. 2A and 2B show top and side views of a light emitting package 110. The package 110 is similar to the package 10 of FIG. 1. Elements of the light emitting package 110 that correspond with elements of the package 10 are labeled by reference numbers offset by 100. The package 110 includes a light emitting chip 112 flip chip bonded to conductive layers 120, 122 disposed on a top principal surface 126 of a chip carrier 114. A gap 128 electrically isolates the conductive layers 120, 122. Lead frame elements 140, 142 are soldered or otherwise electrically contacted and mechanically bonded with the conductive layers 120, 122 disposed on the top principal surface 126 of the chip carrier 114. The lead frame elements 140, 142 each include a bend 148, 154 so that electrical leads 146, 152 distal from the chip carrier 114 are approximately coplanar with a bottom principal surface 150 of the chip carrier 114.

As in the package 10, at least the top principal surface 126 of the chip carrier 114 is electrically insulating, while the chip carrier 114 can be either electrically insulating, or electrically conductive with an insulator layer providing the electrically insulating top principal surface 126. The chip carrier 114 is also preferably substantially thermally conductive. The lead frame 140, 142 is electrically conductive, and is suitably made of copper or another metal. The package 110 as illustrated does not include an encapsulant or phosphor; however, these components are optionally added. If an encapsulant is added, the bottom principal surface 150 of the chip carrier 114 and the leads 146, 152 of the leads should extend outside of the encapsulant.

Advantageously, the light emitting package 110 does not include wire bonds. Rather, electrical connection between the lead frame 140, 142 and the light emitting chip 112 is through the conductive layers 120, 122. As best seen in FIG. 2A, the conductive layers 120, 122 are large area layers, providing good conductance even if the thicknesses of the conductive layers 120, 122 is limited. Moreover, the conductive layers 120, 122 can be reflective layers that reflectively increase light extraction. The light emitting package 110 is suitable for surface mounting on a printed circuit board or other substrate. To perform surface mounting, the leads 146, 152 are soldered or otherwise electrically bonded to bonding bumps, bonding pads, or other electrical terminals of printed circuitry, while the bottom principal surface 150 of the chip carrier 114 is preferably soldered or otherwise thermally bonded to the printed circuit board or other substrate.

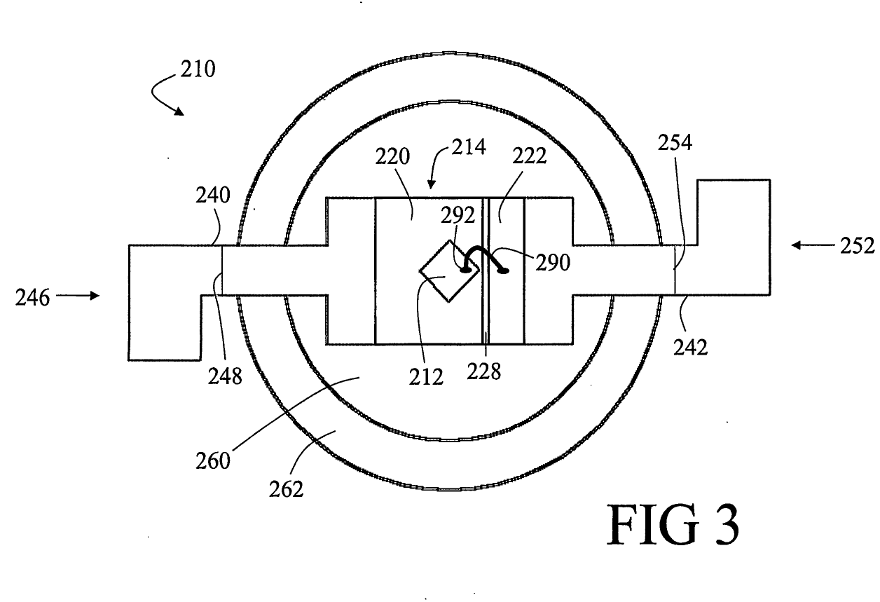

With reference to FIG. 3, a light emitting package 210 is described. The package 210 is similar to the package 10 of FIG. 1. Elements of the light emitting package 210 that correspond with elements of the package 10 are labeled by reference numbers offset by 200. The package 210 includes a light emitting chip 212 bonded to a conductive layer 220 disposed on a top principal surface of a chip carrier 214. Unlike the package 10, however, in the package 210 the light emitting chip 212 is not flip-chip bonded. Rather, the light emitting chip 212 is bonded in a non-inverted configuration and includes an electrically conductive backside serving as an electrode that is electrically bonded to the conductive layer 220 using thermosonic bonding, conductive epoxy, solder, or the like. The front-side electrode of the light emitting chip 212 is wire bonded to another conductive layer 222 separated from the conductive layer 220 by a gap 228. The wire bond 290 reaches across the gap 228 to electrically connect a front-side electrode 292 of the light emitting chip 212 with the conductive layer 222.

Lead frame elements 240, 242 are soldered or otherwise electrically contacted and mechanically bonded with the conductive layers 220, 222 disposed on the top principal surface of the chip carrier 214. Similarly to the corresponding lead frame elements of the packages 10, 110, the lead frame elements 240, 242 each include a bend 248, 254 so that electrical leads 246, 252 are approximately coplanar with a bottom principal surface of the chip carrier 214. Similarly to the package 10, an encapsulant 260 encapsulates the light emitting chip 212, the wire bond 290, the top principal surface of the chip carrier 214, and portions of the lead frame elements 240, 242, while the leads 246, 252 and the bottom principal surface of the chip carrier 214 extend outside of the encapsulant 260. Moreover, the light emitting package 210 includes a phosphor coating 262.

While phosphor-coated encapsulants are shown in FIGS. 1 and 3, it is to be appreciated that encapsulation without a phosphor can be employed instead, or the phosphor can be dispersed in the encapsulant, or the phosphor can be otherwise arranged to interact with light produced by the light emitting chip. Moreover, it is contemplated to include a phosphor layer without an encapsulant, or to include neither an encapsulant nor phosphor, as shown in FIG. 2.

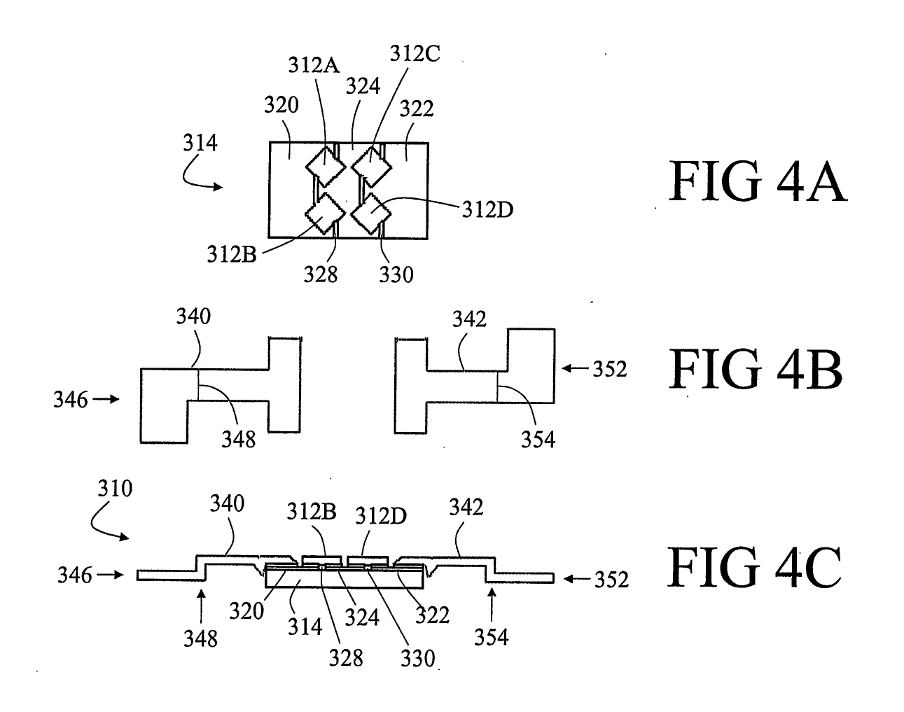

With reference to FIGS. 4A, 4B, and 4C, a light emitting package 310 is described. The package 310 is similar to the package 10 of FIG. 1. Elements of the light emitting package 310 that correspond with elements of the package 10 are labeled by reference numbers offset by 300. The package 310 includes four light emitting chips 312A, 312B, 312C, 312D flip-chip bonded to conductive layers 320, 322, 324 disposed on a top principal surface of a chip carrier 314. The conductive layers 320, 322, 324 are arranged with the layer 324 disposed between the layers 320, 322 and acting as a series interconnect terminal. The conductive layers 320, 324 are separated by a gap 328, while the conductive layers 322, 324 are separated by a gap 330. The light emitting chips 312A, 312B are flip chip bonded across the gap 328 with electrodes bonding to the conductive layers 320, 324, while the light emitting chips 312C, 312D are flip chip bonded across the gap 330 with electrodes bonding to the conductive layers 322, 324. Thus, the light emitting chips 312A, 312B are connected electrically in parallel with each other, and similarly the light emitting chips 312C, 312D are connected electrically in parallel with each other. The parallel combination of chips 312A, 312B is connected electrically in series with the parallel combination of chips 312C, 312D via the series interconnect terminal conductive layer 324.

Lead frame elements 340, 342 are soldered or otherwise electrically contacted and mechanically bonded with the conductive layers 320, 322 disposed on the top principal surface of the chip carrier 314. Similarly to the corresponding lead frame elements of the packages 10, 110, the lead frame elements 340, 342 each include a bend 348, 354 so that electrical leads 346, 352 are approximately coplanar with a bottom principal surface of the chip carrier 314, so that the light emitting chip package 310 can be surface mounted by soldering or otherwise connecting the leads 346, 352 of the lead frame elements 340, 342 to a printed circuit board or other support. Preferably, the surface mounting also includes forming a solder bond or other thermal contact between the bottom principal surface of the chip carrier 314 and the printed circuit board or other support. Although no encapsulant or phosphor is included in the light emitting package 310, it will be appreciated that an encapsulant, phosphor, optical components, or the like are optionally included.

In another embodiment, the light emitting chips 312B, 312D are replaced by zener diodes connected across the gaps 328, 330, respectively. The zener diodes provide electrostatic discharge protection for the light emitting chips 312A, 312C. Moreover, it will be appreciated that other electronic components can be similarly added along with interconnecting circuitry defined by conductive areas on the top principal surface of the chip carrier 314. Such other electronic components can regulate behavior of the light emitting chips, for example by providing input voltage conditioning, current limiting, or the like.

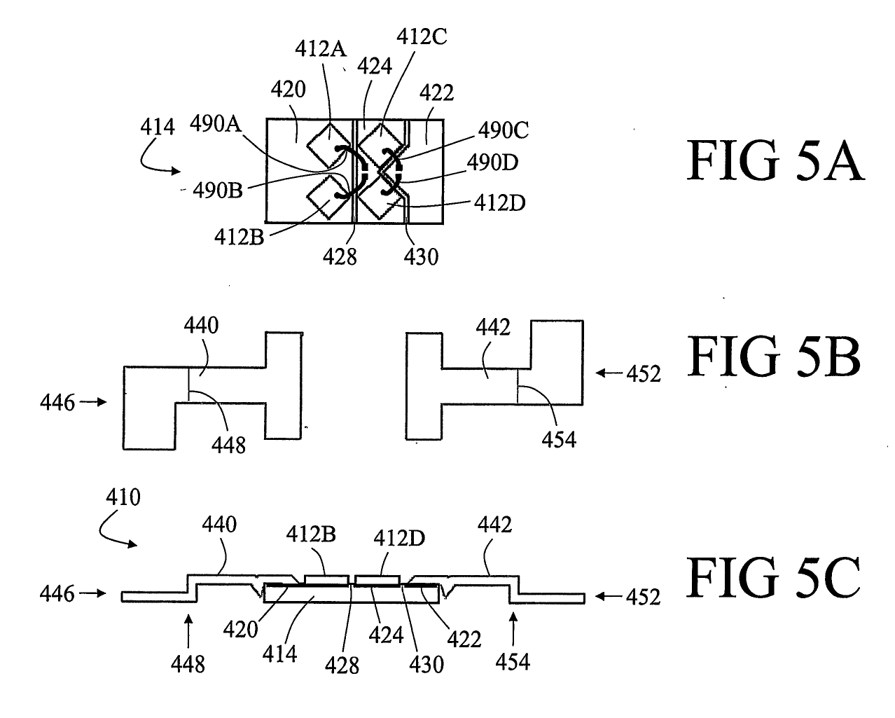

With reference to FIGS. 5A, 5B, and 5C, a light emitting package 410 is described. The package 410 is similar to the package 310 of FIGS. 4A, 4B, and 4C. Elements of the light emitting package 410 that correspond with elements of the package 310 are labeled by reference numbers offset by 100. The package 410 includes four light emitting chip 412A, 412B, 412C, 412D electrically connected with conductive layers 420, 422, 424 disposed on a top principal surface of a chip carrier 414. The conductive layers 420, 422, 424 are arranged with the layer 424 disposed between the layers 420, 422 and acting as a series interconnect terminal. The conductive layers 420, 424 are separated by a gap 428, while the conductive layers 422, 424 are separated by a gap 430. The light emitting chips 412A, 412B are arranged in a non-inverted orientation with an electrically conductive backside of each chip serving as an electrode bonded to the conductive layer 420. Similarly, the light emitting chips 412C, 412D are arranged in a non-inverted orientation with an electrically conductive backside of each chip serving as an electrode bonded to the conductive layer 424. A front-side electrode of the light emitting chip 412A is wire bonded across the gap 428 to the conductive layer 424 by a wire bond 490A. Similarly, a front-side electrode of the light emitting chip 412B is wire bonded across the gap 428 to the conductive layer 424 by a wire bond 490B. A front-side electrode of the light emitting chip 412C is wire bonded across the gap 430 to the conductive layer 422 by a wire bond 490C. A front-side electrode of the light emitting chip 412D is wire bonded across the gap 430 to the conductive layer 422 by a wire bond 490D. Thus, the light emitting chips 412A, 412B are connected electrically in parallel with each other, and similarly the light emitting chips 412C, 412D are connected electrically in parallel with each other. The parallel combination of chips 412A, 412B is connected electrically in series with the parallel combination of chips 412C, 412D via the series interconnect terminal conductive layer 424.

Lead frame elements 440, 442 are soldered or otherwise electrically contacted and bonded with the conductive layers 420, 422 disposed on the top principal surface of the chip carrier 414. Similarly to the corresponding lead frame elements of the packages 10, 110, the lead frame elements 440, 442 each include a bend 448, 454 so that electrical leads 446, 452 are approximately coplanar with a bottom principal surface of the chip carrier 414, so that the light emitting chip package 410 can be surface mounted by soldering or otherwise connecting the leads 446, 452 to a printed circuit board or other support. Preferably, the surface mounting also includes forming a solder bond or other thermal contact between the bottom principal surface of the chip carrier 414 and the printed circuit board or other support. Although no encapsulant or phosphor is included in the light emitting package 410, it will be appreciated that an encapsulant, phosphor, optical components, or the like are optionally included.

In FIGS. 3 and 5 a single wire bond is used to electrically connect a frontside electrode of each chip, with the second electrode of each chip corresponding to the electrically conductive backside of the chip. However, it is also contemplated to employ an insulating backside and two front side contacts that are each wire bonded to one of the conductive films disposed on the front principal surface of the chip carrier.

The light emitting packages described herein are suitably constructed using electronic packaging processes. One example process is as follows. The process preferably starts with a chip carrier wafer which will be diced to produce a large number of light emitting packages each including a chip carrier diced from the chip carrier wafer. If the chip carrier is electrically conductive, it is preferably coated, oxidized, or otherwise processed to form an electrically insulating layer at least on the top principal surface. Two or more patterned conductive layers are formed on the top principal surface of the chip carrier using metal evaporation, electroplating, or the like in conjunction with lithographic techniques that define the electrically isolating gaps between the conductive layers. These patterned conductive layers are the electrical terminal conductive layers, such as the layers 20, 22 of the package of FIG. 1. Optionally, the bottom principal surface of the chip carrier is also metallized to allow for solder attach to improve thermal conductivity through the bottom principal surface. The light emitting chips are attached mechanically and electrically to the chip carriers by flip-chip bonding, wire bonding, or the like. The chip carrier wafer is then diced to produce a plurality of chip carriers with attached light emitting chips.

Each chip carrier produced by the dicing is processed in the example process as follows. The top principal surface of the chip carrier is soldered to the lead frame. Preferably, the two lead frame elements are secured together by tabs or other fasteners during this soldering, and in one embodiment a number of such lead frames are secured together in a linear or two-dimensional array to facilitate automated processing. A transfer molding process is used to form the encapsulant over the light emitting chips, the top principal surface of the chip carrier, and portions of the lead frame. The molding die is designed so that the leads and the bottom principal surface of the chip carrier extend outside the molded encapsulant. The tabs of the lead frames are then cut or trimmed to electrically separate the lead frame elements to produce the final light emitting package that is suitable for surface mounting by soldering or the like.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

What is claimed is:

1. A light emitting package comprising:
a chip carrier having top and bottom principal surfaces;
at least one light emitting chip attached to the top principal surface of the chip carrier; and
a lead frame attached to the top principal surface of the chip carrier.

2. The light emitting package as set forth in claim 1, further comprising:
an encapsulant encapsulating at least the light emitting chip and the top principal surface of the chip carrier, the bottom principal surface of the chip carrier and leads of the lead frame extending outside the encapsulant.

3. The light emitting package as set forth in claim 1, further comprising:
one or more areas of electrically conductive material disposed on the top principal surface of the chip carrier, the attachment of the lead frame to the top principal surface electrically contacting the one or more areas of electrically conductive material.

4. The light emitting package as set forth in claim 3, wherein the one or more areas of electrically conductive material include:
a first area of electrically conductive material defining a first electrical terminal;
a second area of electrically conductive material electrically isolated from the first area, the second area defining a second electrical terminal of opposite electrical polarity from the first electrical terminal;
electrodes of the light emitting chip being electrically connected with the first and second electrical terminals; and
the lead frame being attached to the first and second electrical terminals.

5. The light emitting package as set forth in claim 4, wherein the light emitting chip is flip-chip bonded to the first and second electrical terminals.

6. The light emitting package as set forth in claim 4, wherein the light emitting chip is flip-chip bonded to the first and second electrical terminals using one of thermosonic bonding, solder, and a conductive epoxy.

7. The light emitting package as set forth in claim 4, wherein at least one electrode of the light emitting chip is wire bonded to one of the first and second electrical terminals.

8. The light emitting package as set forth in claim 7, wherein another electrode of the light emitting chip is wire bonded to the other one of the first and second electrical terminals.

9. The light emitting package as set forth in claim 3, wherein:
the one or more areas of electrically conductive material include:
a first area of electrically conductive material defining a first electrical terminal,
a second area of electrically conductive material electrically isolated from the first area, the second area defining a second electrical terminal of opposite electrical polarity from the first electrical terminal, and
a third area of electrically conductive material electrically isolated from the first and second areas of electrically conductive material, the third area of electrically conductive material defining a series interconnection terminal; and
the light emitting chip includes first and second light emitting chips, electrodes of the first light emitting chip being electrically connected with the first and series interconnection electrical terminals and electrodes of the second light emitting chip being electrically connected with the second and series interconnection electrical terminals, and the lead frame being attached to the first and second electrical terminals.

10. The light emitting package as set forth in claim 9, wherein the light emitting chip further includes:
a third light emitting chip, electrodes of the third light emitting chip being electrically connected with the first and series interconnection electrical terminals.

11. The light emitting package as set forth in claim 10, wherein the light emitting chip further includes:
a fourth light emitting chip, electrodes of the fourth light emitting chip being electrically connected with the second and series interconnection electrical terminals.

12. The light emitting package as set forth in claim 9, further including:
at least one zener diode electrically connected with at least one of the first and series interconnection electrical terminals, and the second and series interconnection electrical terminals.

13. The light emitting package as set forth in claim 3, further including:
at least one electronic component electrically contacting the one or more areas of electrically conductive material, the at least one electronic component regulating behavior of the at least one light emitting chip.

14. The light emitting package as set forth in claim 13, wherein the at least one electronic component includes:
a zener diode electrically connected in parallel with the light emitting chip to provide electrostatic discharge protection.

15. The light emitting package as set forth in claim 1, wherein the light emitting chip receives electrical power through the lead frame and does not receive electrical power through the bottom principal surface of the chip carrier.

16. The light emitting package as set forth in claim 1, wherein the bottom principal surface of the chip carrier is electrically isolated from the lead frame.

17. The light emitting package as set forth in claim 1, wherein the lead frame has electrical leads extending from portions of the lead frame attached to the top principal surface of the chip carrier, the electrical leads being shaped to include lead portions approximately coplanar with the bottom principal surface of the chip carrier.

18. The light emitting as set forth in claim 17, wherein the bottom principal surface of the chip carrier is at least one of substantially electrically non-conductive and electrically isolated from the lead frame.

19. The light emitting package as set forth in claim 18, wherein the chip carrier, light emitting chip, and lead frame define a surface mountable unit, the light emitting package further comprising:
printed circuitry, the surface mountable unit being mounted on the printed circuitry with the lead portions approximately coplanar with the bottom principal surface of the chip carrier electrically contacting the printed circuitry.

20. The light emitting package as set forth in claim 19, further comprising:
a printed circuit board including the printed circuitry, the bottom principal surface of the chip carrier being in thermal contact with the printed circuit board.

21. The light emitting package as set forth in claim 19, further comprising:
a printed circuit board on which the printed circuitry is disposed, the bottom principal surface of the chip carrier being in direct contact with the printed circuit board.

22. The light emitting package as set forth in claim 21, wherein the chip carrier is soldered to the printed circuit board.

23. The light emitting package as set forth in claim 21, wherein the chip carrier is soldered to the printed circuit board, said soldered connection being thermally conductive but not conducting electrical current when the light emitting chip is operated.

24. The light emitting package as set forth in claim 21, wherein an attachment between the lead portions contacting the printed circuitry is different from an attachment of the bottom principal surface of the chip carrier contacting the printed circuit board.

25. The light emitting package as set forth in claim 21, further comprising:
an encapsulant encapsulating at least the light emitting chip and the top principal surface of the chip carrier, the bottom principal surface of the chip carrier and at least the lead portions approximately coplanar with the bottom principal surface of the chip carrier extending outside the encapsulant.

26. The light emitting package as set forth in claim 1, wherein the chip carrier comprises:
a semi-insulating silicon wafer.

27. The light emitting package as set forth in claim 1, wherein the chip carrier comprises:
electrically conductive silicon having at least the top principal surface coated with an insulating layer.

28. The light emitting package as set forth in claim 1, wherein the chip carrier comprises:
metal having at least the top principal surface coated with an insulating layer.

29. The light emitting package as set forth in claim 1, wherein the chip carrier comprises:
thermally conductive plastic.

30. The light emitting package as set forth in claim 1, wherein the chip carrier comprises:
ceramic.

31. The light emitting package as set forth in claim 1, wherein the chip carrier is electrically insulating and the lead frame is electrically conductive.

32. A light emitter comprising:
a chip carrier having top and bottom principal surfaces;
at least one light emitting chip attached to the top principal surface of the chip carrier;
a lead frame electrically contacting electrodes of the at least one light emitting chip; and
a support including printed circuitry, the lead frame electrically contacting the printed circuitry, the chip carrier secured to the support without the lead frame intervening therebetween.

33. The light emitter as set forth in claim 32, wherein the lead frame comprises:
a first lead frame element extending from the top principal surface of the chip carrier to a first terminal of the printed circuitry; and
a second lead frame element extending from the top principal surface of the chip carrier to a second terminal of the printed circuitry.

34. The light emitter as set forth in claim 33, wherein the chip carrier further comprises:
a first electrically conductive layer disposed on the top principal surface and electrically contacting the first lead frame element; and
a second electrically conductive layer disposed on the top principal surface and electrically contacting the second lead frame element.

35. The light emitter as set forth in claim 34, wherein the electrodes of the light emitting chip are electrically connected with the first and second electrically conductive layers.

36. The light emitter as set forth in claim 34, wherein the first and second lead frame elements are mechanically bonded to the top principal surface of the chip carrier.

37. The light emitter as set forth in claim 34, wherein the at least one light emitting chip includes at least two light emitting chips, and the chip carrier further comprises:
a third electrically conductive layer disposed on the top principal surface, electrodes of the two light emitting chips contacting the third electrically conductive layer.
